(19) United States
(12) Patent Application Publication
(10) Pub. No.: US 2025/0169335 A1
(43) Pub. Date: May 22, 2025

(54) Display Apparatus

(71) Applicant: LG Display Co., Ltd., Seoul (KR)

(72) Inventors: Hye-Jin Kim, Paju-si (KR); Woo-Seok Noh, Paju-si (KR); Young-June Go, Paju-si (KR); Sung-Ho Lee, Paju-si (KR); Hui-Seong Yu, Paju-si (KR)

(21) Appl. No.: 18/819,504

(22) Filed: Aug. 29, 2024

(30) Foreign Application Priority Data
Nov. 20, 2023 (KR) 10-2023-0160114

(51) Int. Cl. H10K 59/80; H10K 59/124

(52) U.S. Cl. CPC H10K 59/873; H10K 59/124

(57) ABSTRACT

A display apparatus presented herein comprises a substrate including a display area having a plurality of sub-pixels, and a non-display area; a dam in the non-display area; an encapsulation layer including an encapsulation material, the encapsulation layer in the display area and the non-display area; and a flow control unit that controls a flow of the encapsulation material, the flow control unit between the display area and the dam in the non-display area, and the flow control unit surrounds the display area.

### CROSS-REFERENCE TO RELATED APPLICATION

This application claims the priority from Republic of Korea Patent Application No. 10-2023-0160114, filed on Nov. 20, 2023, which is hereby incorporated by reference in its entirety.

### BACKGROUND

### Field

The present disclosure relates to a display apparatus, and more particularly, for example, without limitation, to a display apparatus that can minimize or at least reduce the area of the bezel.

### Description of Related Art

Recently, the importance of display apparatus has increased with the development of multimedia. Various display apparatus, such as liquid crystal display, a field emission display, an inorganic light emitting display and an organic light emitting display, have been proposed.

As this display apparatus is applied to small portable electronic devices such as smartphones and tablet PC, the bezel area should be minimized, eliminated, or at least reduced for a relatively large screen even in a small size display apparatus and an attractive appearance.

The description provided in the description of the related art section should not be assumed to be prior art merely because it is mentioned in or associated with the description of the related art section. The description of the related art section may include information that describes one or more embodiments of the subject technology, and the description in this section does not limit embodiments of the present disclosure.

### SUMMARY

There have been recognized the limitation on minimizing, eliminating, or at least reducing a bezel area of the display apparatus. Accordingly, an object of the present disclosure is to provide a display apparatus that can significantly reduce the bezel area by minimizing or at least reducing the number of dams by controlling the flow of organic materials when forming an encapsulation layer.

A display apparatus according to one or more embodiments of the present disclosure comprises a substrate including a display area having a plurality of sub-pixels, and a non-display area; a dam in the non-display area; an encapsulation layer including an encapsulation material, the encapsulation layer in the display area and the non-display area; and a flow control unit that controls a flow of the encapsulation material, the flow control unit between the display area and the dam in the non-display area, and the flow control unit surrounds the display area.

The flow control unit includes a plurality of flow control patterns on the planarization layer, and the plurality of flow control patterns can be made of the same material as the bank layer.

The flow control unit includes a plurality of flow control patterns on the interlayer insulating layer, and a flow control pattern of the plurality of flow control patterns includes a first flow control layer including a same material as the planarization layer on a interlayer insulating layer and a second flow control layer including a same material as a bank layer on the first flow control layer.

The encapsulation layer includes a first encapsulation layer that covers the light emitting device and the flow control pattern, a second encapsulation layer on the first encapsulation layer, and a third encapsulation layer on the second encapsulation layer. The first encapsulation layer on a flow control pattern of the plurality of flow control patterns can be protruded upward by the flow control pattern, and a protruding area of the first encapsulation layer can have hydrophobic characteristics.

The protruding area of the first encapsulation layer can have hydrophobic characteristics.

The size of the flow control pattern can be increased from the display area to the dam, and the density of the flow control pattern can be increased from the display area toward the dam.

The size of the flow control pattern on a corner portion of the substrate can be larger than the size of the flow control pattern on four sides of the substrate, and the density of the flow control patterns on corners of the substrate can be greater than the density of the flow control patterns on four sides of the substrate.

According to embodiments of the present disclosure, it is possible to reduce the bezel area by minimizing or at least reducing the number of dams by controlling the flow of organic materials when forming an encapsulation layer.

According to embodiments of the present disclosure, the flow control unit may control the flow speed of the encapsulation material spreading, in order to prevent the encapsulation material from flowing out of the display apparatus in case where only one dam is disposed or the dam is not disposed.

According to embodiments of the present disclosure, the flow control pattern may control the flow speed of the encapsulation material spreading within the flow control unit to control the area in which the encapsulation material is spreading during the coating time of the encapsulation material in order to prevent the encapsulation material from flowing out of the display apparatus in case where only one dam is disposed or the dam is not disposed.

The effects according to the present disclosure are not limited to the contents exemplified above, and more various effects are included in the present disclosure.

### BRIEF DESCRIPTION OF THE DRAWINGS

The above and other embodiments, features and other advantages of the present disclosure will be more clearly understood from the following detailed description taken in conjunction with the accompanying drawings, in which:

FIG. 1 is a schematic block diagram of an organic light emitting display apparatus according to one or more embodiments of the present disclosure.

FIG. 2 is the schematic block diagram of a sub-pixel of the organic light emitting display apparatus according to one or more embodiments of the present disclosure.

FIG. 3 is a circuit diagram conceptually showing the sub-pixel of the organic light emitting display apparatus according to one or more embodiments of the present disclosure.

FIG. 4 is a plan view schematically showing the structure of the display apparatus according to one or more embodiments of the present disclosure.

FIG. 5 is a view showing the structure of a flow control unit of the display apparatus and control of the flow rate of encapsulation material in the flow control unit according to one or more embodiments of the present disclosure.

FIGS. 6A to 6C are views showing different shapes of flow control patterns of the display apparatus according to one or more embodiments of the present disclosure.

FIGS. 7A and 7B are views showing different structures of flow control patterns of the display apparatus according to one or more embodiments of the present disclosure.

FIGS. 8A and 8B are views showing other structures of flow control patterns of the display apparatus according to one or more embodiments of the present disclosure.

FIG. 9 is a view showing the structure of the flow control pattern at the corner of the display apparatus according to one or more embodiments of the present disclosure.

FIG. 10 is a cross-sectional view showing the structure of the display apparatus according to a first embodiment of the present disclosure.

FIG. 11 is a cross-sectional view showing the structure of the display apparatus according to a second embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure and methods for achieving them will be made clear from embodiments described in detail below with reference to the accompanying drawings. The present disclosure may, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains, and the present disclosure is defined only by the scope of the appended claims.

Shapes, sizes, dimensions (e.g., length, width, height, thickness, radius, diameter, area, etc.), ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein. When terms such as “include,” “have,” “comprise,” “constitute,” “make up of,” “formed of,” and “consist of” and the like mentioned in this disclosure are used, other parts may be added unless the term “only” is used herein. When a component is expressed as being singular, being plural is included unless otherwise specified.

The word “exemplary” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.” A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In analyzing a component, an error range is interpreted as being included even when there is no explicit description.

In describing a positional relationship, for example, when a positional relationship of two parts is described as being “on”, “above”, “over”, “below”, “under”, “beside”, “beneath”, “near”, “close to,” “adjacent to”, “on a side of”, “next” or the like, unless “immediately” or “directly” is used, one or more other parts may be located between the two parts.

Spatially relative terms, such as “under,” “below,” “beneath”, “lower,” “over,” “upper” and the like, may be used herein for ease of description to describe one element or feature's relationship to another element(s) or feature(s) as illustrated in the figures. It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the term “below” can encompass both an orientation of below and above. Similarly, the term “above” or “over” can encompass both an orientation of “above” and “below”.

In describing a temporal relationship, for example, when a temporal predecessor relationship is described as being “after,” “subsequent to,” “following,” “next,” “before,” or the like, unless “immediately” or “directly” is used, cases that are not continuous may also be included.

Although the terms “first”, “second”, “A”, “B”, “(a)”, “(b)” and the like are used to describe various components, these components are not substantially limited by these terms. These terms are used only to distinguish one component from another component. Therefore, a first component described below may substantially be a second component within the technical spirit of the present disclosure.

In describing the components of the invention, terms such as first, second, A, B, (a), (b), etc. may be used. These terms are only for distinguishing the elements from other elements, and the essence, order, or number of the elements are not limited by the terms. When it is described that a component is “coupled” or “connected” to another component, the component may be directly coupled or connected to the other component, but indirectly without specifically stated. It should be understood that other components may be “interposed” between each component that is connected or can be connected.

As used herein, the term “apparatus” may include a display apparatus such as a liquid crystal module (LCM) including a display panel and a driving unit for driving the display panel, and an organic light emitting display module (OLED module). Further, the term “apparatus” may further include a notebook computer, a television, a computer monitor, a vehicle electric apparatus including an apparatus for a vehicle or other type of vehicle, and a set electronic apparatus or a set apparatus such as a mobile electronic apparatus of a smart phone or an electronic pad, etc., which are a finished product (complete product or final product) including LCM and OLED module.

Accordingly, the apparatus in the invention may include the display apparatus itself such as the LCM, the OLED module, etc., and the application product including the LCM, the OLED module, or the like, or the set apparatus, which is the apparatus for end users.

This disclosure can be applied to the various display apparatus. For example, the display apparatus of this disclosure can be applied to various display apparatus such as an organic light emitting display apparatus, an inorganic light emitting diode (ILED) display device, a liquid crystal display apparatus, an electrophoretic display apparatus, a quantum dot display apparatus, a micro-LED (Light Emitting Device) display apparatus, and a mini-LED display apparatus, without being limited thereto. However, in the following description, the organic light emitting display apparatus will be described as an example for convenience of explanation.

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In one or more embodiments of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one embodiment of the present disclosure may be the drain electrode in another embodiment of the present disclosure, and the drain electrode in any one embodiment of the present disclosure may be the source electrode in another embodiment of the present disclosure.

Hereinafter, the present disclosure will be described in detail with reference to the drawings presented herein.

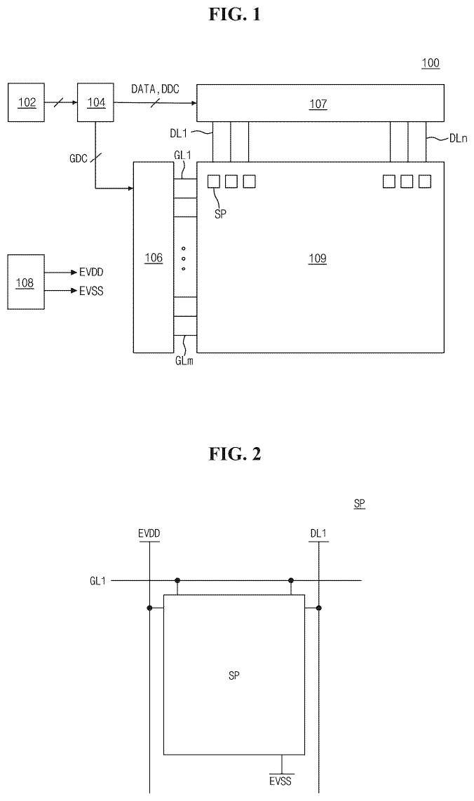

FIG. 1 is the schematic block diagram and FIG. 2 is the schematic block diagram of the sub-pixel of the organic light emitting display apparatus according to one or more embodiments of the present disclosure.

As shown in FIG. 1, the organic light emitting display apparatus 100 includes an image processing unit 102, a timing controlling unit 104, a gate driving unit 106, a data driving unit 107, a power supplying unit 108, a display panel 109, and the like. The embodiments of the present disclosure are not limited thereto. Meanwhile, all the components of each display apparatus according to all embodiments of the present disclosure are operatively coupled and configured.

The image processing unit 102 outputs an image data supplied from outside and a driving signal for driving various devices. For example, the driving signal from the image processing unit 102 can include a data enable signal, a vertical synchronizing signal, a horizontal synchronizing signal, a clock signal, and the like, for example, from an external device such as a host system. Here, the horizontal synchronization signal is a signal representing a time taken to display one horizontal line of a screen and the vertical synchronization signal is a signal representing a time taken to display a screen of one frame. The data enable signal may correspond to a signal indicating a period for which a data voltage is supplied to the pixel.

The image data and the driving signal are supplied to the timing controlling unit 104 from the image processing unit 102. The timing controlling unit 104 writes and outputs gate timing controlling signal GDC for controlling the driving timing of the gate driving unit 106 and data timing controlling signal DDC for controlling the driving timing of the data driving unit 107 based on the driving signal from the image processing unit 102.

The gate driving unit 106 outputs the scan signal to the display panel 109 in response to the gate timing control signal GDC supplied from the timing controlling unit 104. For example, the gate driving unit 106 may be a circuit for driving a plurality of gate lines GL1 to GLm, and can supply scan signals to the plurality of gate lines GL1 to GLm. The gate driving unit 106 outputs the scan signal through a plurality of gate lines GL1 to GLm. In this case, the gate driving unit 106 may be formed in the form of an integrated circuit (IC), but is not limited thereto. The gate driving unit 106 includes various gate driving circuits, and the gate driving circuits may be directly formed on the substrate 110. In this case, the gate driving unit 106 may be a gate-in-panel (GIP), but is not limited thereto.

As another example, the gate driving unit 106 may be configured with at least one gate IC. As an example, the gate driving unit 106 may be connected to the display panel 100, for example, in a tape automated bonding (TAB) method, a chip on glass (COG) method, a chip on panel (COP) method, or a chip on film (COF) method, without being limited thereto.

The data driving unit 107 outputs the data voltage to the display panel 109 in response to the data timing control signal DDC input from the timing controlling unit 104. The data driving unit 107 samples and latches the digital data signal DATA supplied from the timing controlling unit 104 to convert it into the analog data voltage based on the gamma voltage. For example, the data driving unit 107 may be a circuit for driving the plurality of data lines DL1 to DLn, and can supply data signals to the plurality of data lines DL1 to DLn. The data driving unit 107 outputs the data voltage through the plurality of data lines DL1 to DLn. In this case, the data driving 107 may be mounted on the upper surface of the display panel 109 in the form of an integrated circuit (IC), but is not limited thereto.

The power supplying unit 108 outputs a high potential voltage VDD and a low potential voltage VSS etc., on the basis of an external input voltage supplied from the outside, to supply these to the display panel 109. The high potential voltage VDD is supplied to the display panel 109 through the first power line EVDD and the low potential voltage VSS is supplied to the display panel 109 through the second power line EVSS. In this time, the power supplying unit 108 may generate and output a voltage needed for driving of the gate driving unit 106, a voltage needed for driving of the data driving unit 107, and a voltage needed for driving of a memory, in addition to the high potential voltage VDD and the low potential voltage VSS, that is, the voltage from the power supplying unit 108 are applied to the data driving unit 107 or the gate driving unit 106 to drive thereto.

The display panel 109 displays the image based on the data voltage from the data driving unit 107, the scan signal from the gate driving unit 106, and the power from the power supplying unit 108.

The display panel 109 includes a plurality of sub-pixels SP to display the image. The plurality of sub pixels SP is a minimum unit which configures the display area and n sub pixels SP form one pixel. Each of the plurality of sub pixels SP may emit light having different wavelengths from each other. The plurality of sub pixels may include first to third sub pixels which emit different color light from each other. For example, the sub-pixel SP can include Red sub-pixel, Green sub-pixel, and Blue sub-pixel. Further, the sub-pixel SP can include White sub-pixel, the Red sub-pixel, the Green sub-pixel, and the Blue sub-pixel. The White sub-pixel, the Red sub-pixel, the Green sub-pixel, and the Blue sub-pixel may be formed in the same area or may be formed in different areas. However, embodiments of the present disclosure are not limited thereto. As an example, the sub-pixel SP of other colors such as magenta, cyan, or yellow may be alternatively or additionally included, without being limited thereto.

For example, the plurality of sub pixels SP may include red, green, and blue sub-pixels, in which the red, green, and blue sub-pixels may be disposed in a repeated manner. Alternatively, the plurality of sub pixels SP may include red, green, blue, and white sub-pixels, in which the red, green, blue, and white sub-pixels may be disposed in a repeated manner, or the red, green, blue, and white sub-pixels may be disposed in a quad type. For example, the red sub pixel, the blue sub pixel, and the green sub pixel may be sequentially disposed along a row direction, or the red sub pixel, the blue sub pixel, the green sub pixel, and the white sub pixel may be sequentially disposed along the row direction. However, in one or more embodiments of the present disclosure, the color type, disposition type, and disposition order of the sub-pixels are not limiting, and may be configured in various forms according to light-emitting characteristics, device lifespans, and device specifications.

Meanwhile, the sub-pixels may have different light-emitting areas according to light-emitting characteristics. For example, a sub-pixel that emits light of a color different from that of a blue sub-pixel may have a different light-emitting area from that of the blue sub-pixel. For example, the red sub-pixel, the blue sub-pixel, and the green sub-pixel, or the red sub-pixel, the blue sub-pixel, the white sub-pixel, and the green sub-pixel may each has a different light-emitting area.

As shown in FIG. 2, one sub-pixel SP may be connected to the gate line GL1, the data line DL1, the first power line EVDD, and the second power line EVSS. The sub-pixel SP may include a plurality of thin film transistors and a storage capacitor depending on the configuration of the pixel circuit. For example, the sub-pixel SP may include two transistors and one capacitor (it is called 2T1C), but is not limited thereto, and may include more or less elements. The sub-pixel SP may be composed of 3T1C, 4T1C, 5T1C, 6T1C, 7T1C, 3T2C, 4T2C, 5T2C, 6T2C, 7T2C, 8T2C, etc.

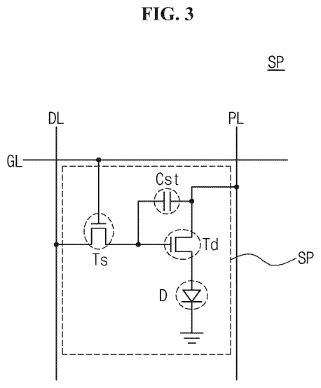

FIG. 3 is the circuit diagram illustrating the sub-pixel SP of the organic light emitting display apparatus 100 according to one or more embodiments of the present disclosure.

As shown in FIG. 3, the organic light emitting display apparatus 100 according to one or more embodiments of the present disclosure includes the gate line GL, the data line DL, and the power line PL crossing each other for defining the sub-pixel SP. A switching thin film transistor Ts, a driving thin film transistor Td, a storage capacitor Cst, and a light emitting device D are disposed in the sub-pixel SP.

The switching thin film transistor Ts is connected to the gate line GL and the data line DL, in particular, the gate electrode of the switching thin film transistor Ts is connected to the gate line GL, and the drain electrode of the switching thin film transistor Ts is connected to the data line DL, and the driving thin film transistor Td and the storage capacitor Cst are connected between the switching thin film transistor Ts and the power line PL. The light emitting device D is connected to the driving thin film transistor Td.

In the organic light emitting display apparatus having this structure, when the switching thin film transistor Ts is turned on according to the gate signal applied to the gate line GL, the data signal applied to the data line DL is applied to the gate electrode of the driving thin film transistor Td and one electrode of the storage capacitor Cst through the switching thin film transistor Ts.

The driving thin film transistor Td is turned on according to the data signal applied to the gate electrode thereof. As a result, the current proportional to the data signal is supplied to the light emitting device D from the power line PL through the driving thin film transistor Td and then the light emitting device D emits light with a luminance proportional to the current flowing through the driving thin film transistor Td.

The driving thin film transistor Td is turned on according to the data signal applied to the gate electrode. As a result, the current proportional to the data signal is supplied to the light emitting device D from the power line PL through the driving thin film transistor Td and then the light emitting device D emits light with a luminance proportional to the current flowing through the driving thin film transistor Td.

In FIG. 3, only two thin film transistors Td and Ts and one capacitor Cst are provided, but the present disclosure is not limited thereto. Three or more thin film transistors and two or more capacitors may be provided in the present disclosure.

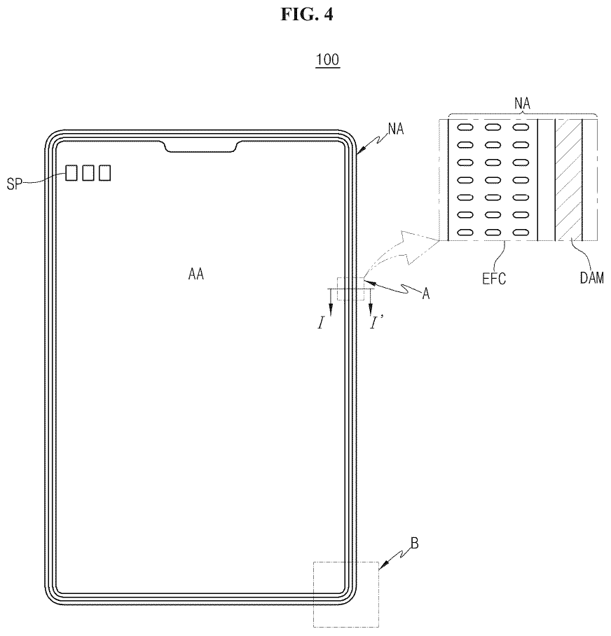

FIG. 4 is the plan view schematically showing the structure of the display apparatus 100 according to one or more embodiments of the present disclosure.

As shown in FIG. 4, the display apparatus 100 according to one or more embodiments of the present disclosure includes a display area AA for displaying an image and a non-display area NA disposed outside the display area AA. The non-display area NA may refer to an area outside of the display area AA. Several types of signal lines may be disposed in the non-display area NA, and several types of driving circuits may be connected thereto. At least a portion of the non-display area NA may be bent to be invisible from the front surface of the display apparatus 100 or may be covered by a case or housing (not shown) of the display apparatus 100. The non-display area NA may be also referred to as an edge area or a bezel area. For example, the non-display area NA may fully or partially surround the display area AA, for example, the non-display area NA may be adjacent to the display area AA and disposed at the outside from the display area AA.

A plurality of pixels P are arranged in the display area AA, and each pixel P includes a plurality of sub-pixels SP. At this time, the sub-pixel SP may be a red (R) sub-pixel, a green (G) sub-pixel, or a blue (B) sub-pixel, without being limited thereto. Further, the sub-pixel SP may be a white (W) sub-pixel.

Although not shown in FIG. 4, a plurality of gate lines and data lines are arranged in the display area AA, and the sub-pixel SP is disposed in the intersection area of the gate line and data line. In each sub-pixel SP, a thin film transistor that is a switching element and a display device to display the image are disposed.

The display device may include various display devices. For example, the display device may be an organic light emitting display device, a liquid crystal display device, a quantum dot display device, a micro-LED display device, or a mini-LED display device, but is not limited thereto.

The gate driving unit and the data driving unit that apply various signals to the sub-pixel SP may be disposed in the non-display area NA. The gate driving unit applies the scan signal to the sub-pixel SP through the gate line, and the data driving unit applies the image signal to the sub-pixel SP through the data line.

A dam DAM surrounding the display area AA is formed in the non-display area NA. When the thin film transistor or the organic light emitting layer of the display apparatus 100 is exposed to external impurities such as air or moisture, the thin film transistor or the organic light emitting layer is deteriorated and the display apparatus 100 is defective. Therefore, an encapsulation layer (not shown) must be formed in the display apparatus 100 to seal the display apparatus 100 from the external environment. As will be explained later, when applying the encapsulation material to form an encapsulation layer, the dam DAM is formed in the non-display area NA to block the flow of the encapsulation material, thereby preventing the encapsulation material from flowing to the outside of the display apparatus 100. The encapsulation layer may include an inorganic insulating material and/or an organic encapsulation layer. For example, the inorganic encapsulation layer may include an inorganic insulating material capable of low-temperature deposition, such as silicon nitride (SiN), silicon oxide (SiO), silicon oxynitride (SiON) and aluminum oxide (AlO). For example, the organic encapsulation layer may include an organic insulating material, such as acrylic resin, epoxy resin, polyimide, polyethylene and silicon oxycarbide (SiOC). In a general display apparatus, a plurality of dams DAM are disposed to surround the outside of the display area AA to reliably prevent the encapsulation material from flowing out. The reason for forming multiple dams DAM is as follows.

If the encapsulation layer is not formed in a uniform thickness in the entire area of the display apparatus 100, the image quality is deteriorated due to light refraction at the interface of the encapsulation layer. When the encapsulation material is dispensed and spread in the entire area of the display apparatus 100, if the spreading speed is not uniform, the encapsulation material is not formed in the uniform thickness. That is, when the encapsulation material is spreading in all directions of the display apparatus 100, the encapsulation material is spreading at different speeds depending on the direction, so that a larger amount of the encapsulation material than the set amount is applied to certain areas and a smaller amount than the set amount to other areas. As a result, the cured encapsulation layer is formed in the non-uniform thickness.

The deterioration of the image quality occurs especially when the encapsulation layer is formed in the thickness less than the set thickness. Therefore, in order to form the entire encapsulation layer in the thickness greater than the set thickness in the general display apparatus, an amount of encapsulation material larger than the set amount should be dispensed, considering the difference in spreading speed. Further, a plurality of dams DAM must be formed in the non-display area to reliably block the encapsulation material exceeding the set amount from spreading to the outside.

However, when the display apparatus 100 includes a plurality of dams DAM, the bezel area of the display apparatus 100 is increased due to the increase of the area of the non-display area NA. Therefore, it is difficult to meet the recent demand for the bezel-less display apparatus 100.

In the present disclosure, the bezel area is minimized or at least reduced by providing only one dam DAM or completely removing the dam DAM, but the encapsulation material does not flow out of the display apparatus 100 when the encapsulation material is coated.

The encapsulation layer is formed by coating the encapsulation material over the entire area of the display apparatus 100 and then curing it. That is, after the encapsulation material is dispensed and spread throughout the display apparatus 100 for a predetermined coating time, the light such as ultraviolet rays is irradiated to harden the coated encapsulation material to form the encapsulation layer. Therefore, when the dispensed encapsulation material is spread at a high speed, the encapsulation material flows out beyond the dam DAM in the non-display area NA during the predetermined coating time.

Further, since the encapsulation material spread to the sides of the display apparatus 100 may be flowing from the sides to the corner area, the encapsulation material flowing from both sides may be collected in the corner area. In this case, the excessively coated encapsulation material may be flowing out of the display apparatus 100.

As described above, when coating the encapsulation material to the display apparatus 100, the encapsulation material is not uniformly coated throughout the display apparatus 100 depending on the location and various situations, and this non-uniform coating of the encapsulation material causes the defects that the encapsulation material flows out of the display apparatus 100.

In the present disclosure, by controlling the flow speed of the encapsulation material to control the size of the area in which the encapsulation material is spread during the coating time of the encapsulation material, even when only one dam DAM is disposed or when there is no dam DAM, the encapsulation material is not flow out from the display apparatus 100.

As shown in FIG. 4, in the present disclosure, a flow control unit EFC is provided in the non-display area NA to control the flow speed of the encapsulation material spreading in the non-display area NA. At this time, the flow control unit EFC is formed along the perimeter of the display area AA at inner region of the dam DAM of the non-display area NA. That is, the flow control unit EFC may be formed between the display area AA and the dam DAM. However, the flow control unit EFC is not limited to this and may extend from the non-display area NA to the display area AA.

A flow control pattern 152 is formed in the flow control unit EFC. The flow control pattern 152 includes a plurality of patterns made of the organic material or the inorganic materials to reduce the flow speed of the encapsulation material.

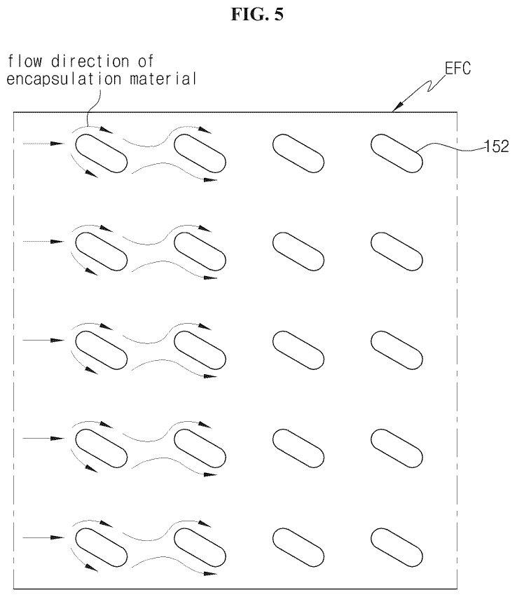

FIG. 5 is a view showing the structure of the flow control unit EFC of the display apparatus 100 and control of the flow speed of the encapsulation material in the flow control unit EFC according to one or more embodiments of the present disclosure.

As shown in FIG. 5, the flow control unit EFC includes a plurality of flow control patterns 152. Since the flow control pattern 152 has the shape of protruding patterns, the encapsulation material spreading into the non-display area NA is blocked by the flow control pattern 152, the flow of the encapsulation material is delayed and thus the spreading speed of the encapsulation material is decreased. Further, since the encapsulation material blocked by the flow control pattern 152 is flowing along the edge of the flow control pattern 152, the spreading distance of the encapsulation material is increased and thus the spreading speed of the encapsulation material is decreased. In addition, since a certain amount of encapsulation material is filled in the space between the flow control patterns 152, the spreading speed of the encapsulation material is also decreased.

In FIG. 5, the flow control pattern 152 is formed in an elongated oval shape, but the flow control pattern 152 is not limited to this shape, and the plurality of flow control patterns 152 may have same or different size, in addition, a distance between two adjacent control patterns among the plurality of flow control patterns 152 may be same or different. However, the present disclosure is not limited thereto.

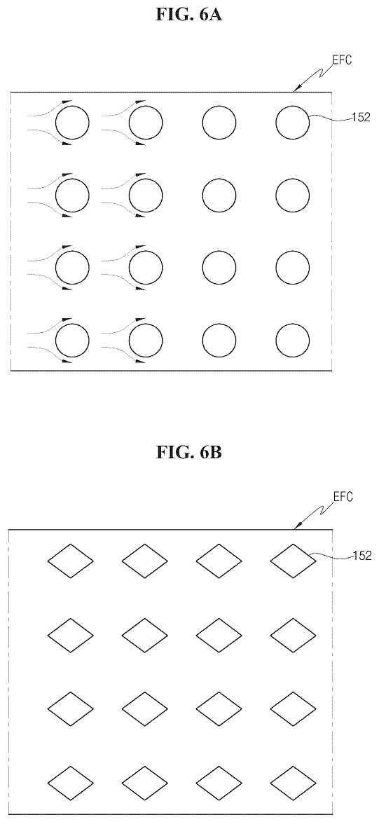

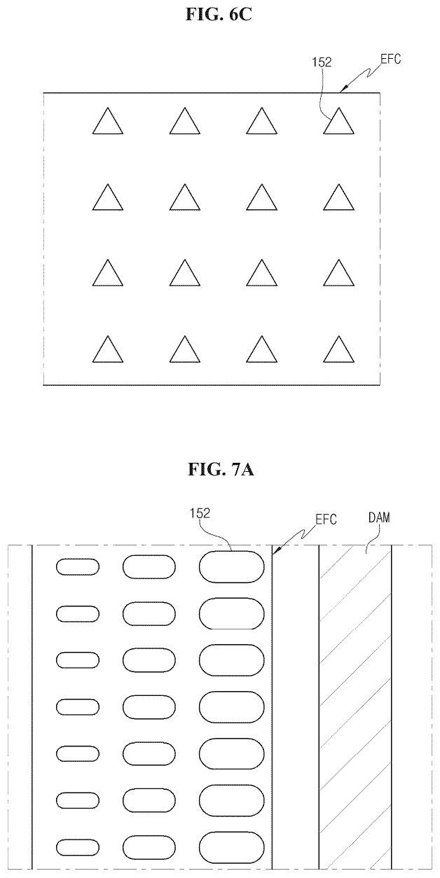

FIG. 6A, FIG. 6B and FIG. 6C are views showing different shapes of the flow control pattern 152 of the display apparatus 100 according to one or more embodiments of the present disclosure.

As shown in FIG. 6A, the flow control pattern 152 can be formed in a circular shape and can be disposed in the entire area of the flow control unit EFC. At this time, the flow control pattern 152 may have the same size in the entire area of the flow control unit EFC, but may have different sizes depending on the location, for example, in one direction, the size of the flow control pattern 152 may gradually increase or decrease, but the present disclosure is not limited thereto.

As shown in FIGS. 6B and 6C, the flow control pattern 152 may be formed in a square or triangular polygon shape, but is not limited thereto and may be formed in various polygonal shapes such as a pentagon or hexagon. In addition, in one direction, the size of the flow control pattern 152 being formed in one of various polygonal shapes may gradually increase or decrease, but the present disclosure is not limited thereto.

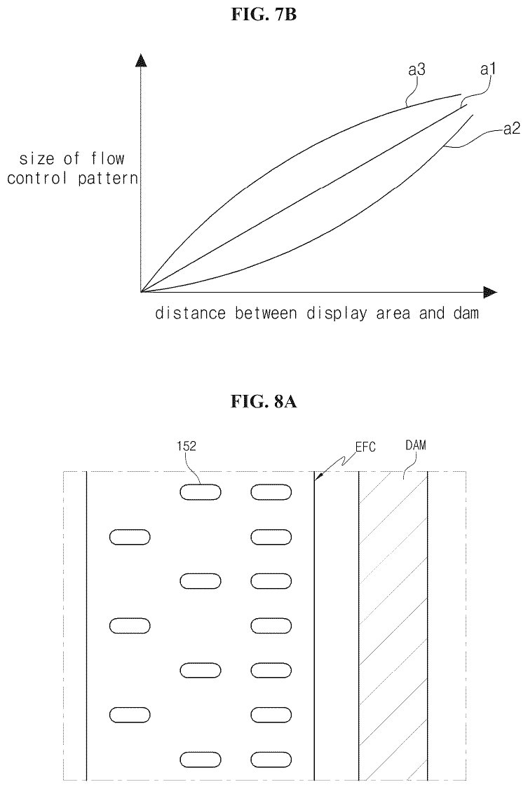

FIGS. 7A and 7B are diagrams showing different structures of the flow control pattern 152 of the display apparatus 100 according to one or more embodiments of the present disclosure. At this time, in FIG. 7A, the shape of the flow control pattern 152 is illustrated as an elongated oval, but it is not limited to this shape and may be formed in a circular or polygonal shape.

As shown in FIG. 7A, the size of the flow control pattern 152 formed in the flow control unit EFC is increased as it goes outward from the display area AA. In other words, the size of the flow control unit EFC is increased toward the dam DAM for the following reasons.

The flow control pattern 152 controls the flow speed of the encapsulation material spreading within the flow control unit EFC to control the area in which the encapsulation material is spreading during the coating time of the encapsulation material in order to prevent the encapsulation material from flowing out of the display apparatus 100 in case where only one dam DAM is disposed or the dam DAM is not disposed.

However, if the flow speed of the encapsulation material is slow overall within the flow control unit EFC, the encapsulation material may be hardened by excessive exposure to light before it reaches the dam DAM. This may cause the defect in which the encapsulation layer fails to encapsulate the entire area of the display apparatus 100.

Therefore, the flow speed should be increased in most areas of the flow control unit EFC to form the encapsulation layer over the entire area of the display apparatus 100, but the flow speed should be decreased near the dam DAM to prevent the encapsulation material to be over-flowing beyond the dam DAM, thus, the size of the flow control unit EFC may be increased toward the dam DAM.

When the encapsulation material is spreading in the flow control unit EFC, since the encapsulation material flows along the edge of the flow control pattern 152, the length of the flow path is increased. Accordingly, as the size of the flow control pattern 152 is increased, the edge length of the flow control pattern 152 is also increased, thereby increasing the length of the flow path. Further, as the size of the flow control pattern 152 is decreased, the edge length of the flow control pattern 152 is also decreased, thereby decreasing the length of the flow path.

In the present disclosure, the size of the flow control pattern 152 formed near the display area AA inside the flow control unit EFC is the smallest, and the size of the flow control pattern 152 formed near the dam DAM is the largest. Therefore, the flow speed of the encapsulation material near the dam DAM is lower than the flow speed near the display area AA, so that the encapsulation layer is formed over the entire area of the display apparatus 100, but the encapsulation material is not over-flowing beyond the dam DAM.

As shown in FIG. 7B, the size of the flow control pattern 152 may be increased linearly from the display area AA to the dam DAM, and the size of the flow control pattern 152 may be increased exponentially. Further, the size of the flow control pattern 152 may be increased logarithmically.

In other word, the size of the flow control pattern 152 may be increased in the various ways from the display area AA to the dam DAM in accordance with the type of encapsulation material, the width of the flow control unit EFC, and the shape of the flow control pattern 152. For example, according to the type of encapsulation material, the width of the flow control unit EFC, and the shape of the flow control pattern 152, the size of the flow control pattern 152 may be increased linearly, exponentially or logarithmically from the display area AA to the dam DAM.

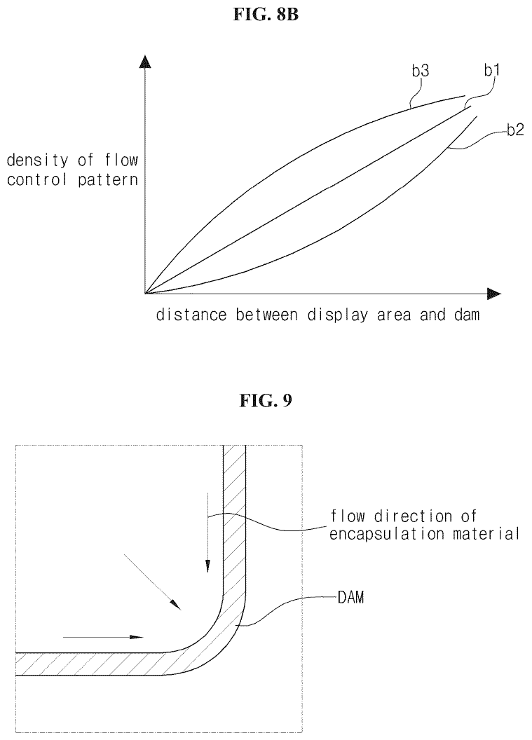

FIGS. 8A and 8B are diagrams showing another structure of the flow control pattern 152 of the display apparatus 100 according to one or more embodiments of the present disclosure. At this time, in FIG. 8A, the flow control pattern 152 has the elongated oval shape, but it is not limited to this shape and may be formed in a circular or polygonal shape.

When the encapsulation material is spread in the flow control unit EFC, the encapsulation material is flowing along the edge of the flow control pattern 152, thereby increasing the length of the flow path. Therefore, the length of the flow path is increased as the number of flow control patterns 152 is increased, and the length of the flow path is decreased as the number of flow control patterns 152 is decreased.

In the present disclosure, the number of flow control patterns 152 formed near the display area AA inside the flow control unit EFC, that is, the density of the flow control patterns 152 is minimized or at least reduced, and the density of the flow control pattern 152 formed near the dam DAM is maximized or at least increased. As a result, the flow speed of the encapsulation material near the dam DAM is smaller than that near the display area AA to form the encapsulation layer over the entire area of the display apparatus 100 and to prevent the encapsulation material to be over-flowing beyond the dam DAM.

As shown in FIG. 8B, the density of the flow control pattern 152 may be increased linearly or exponentially from the display area AA to the dam DAM. Further, the density of the flow control pattern 152 may be increased logarithmically.

In other word, the density of the flow control pattern 152 may be increased in the various ways from the display area AA to the dam DAM in accordance with the type of encapsulation material, the width of the flow control unit EFC, and the shape of the flow control pattern 152. For example, according to the type of encapsulation material, the width of the flow control unit EFC, and the shape of the flow control pattern 152, the density of the flow control pattern 152 may be increased linearly, exponentially or logarithmically from the display area AA to the dam DAM.

Further, the flow control pattern 152 may be formed in different shapes, sizes, and densities depending on the location. For example, areas A and B in FIG. 4 represent four sides and corners of the display apparatus 100, respectively. When the encapsulation material is dispensed onto the display apparatus 100 to coat the encapsulation over the entire area of the display apparatus 100, more of the encapsulation material is concentrated in the corner area for the following reasons.

As shown in FIG. 9, not only the encapsulation material that is directly dispensed and spread in the corner portion, but also a portion of the encapsulation material is flowing through the four sides is collected in the corner portion of the display apparatus 100. Accordingly, while an appropriate amount of encapsulation material is coated in the four sides, an excessive amount of encapsulation material is coated in the corner portions, so that the encapsulation material is over-flowing beyond the dam DAM and then that the encapsulation material is flow out of the display apparatus 100 at the corner portions.

In the present disclosure, in order to prevent this phenomenon, the flow speed of the encapsulation material at the corner portions is lower than that of the encapsulation material at the four sides to prevent the encapsulation material to be over-flowing at the corner portions. For example, the size or density of the flow control pattern 152 at the corner portions may be greater than those of the flow control pattern 152 at the four sides. However, the present disclosure is not limited thereto.

That is, as the size of the flow control pattern 152 is increased, the flow speed of the encapsulation material is decreased, and as the size of the flow control pattern 152 is decreased, the flow speed of the encapsulation material is increased, so that the size of the flow control pattern formed at the corner is larger than the size of the flow control pattern 152 formed on the four sides. As a result, the flow speed of the encapsulation material at the corner can be decreased to harden the encapsulation material before the encapsulation material over-flows beyond the dam DAM and then flow out of the display apparatus 100.

Further, as the density of the flow control pattern 152 is increased, the flow speed of the encapsulation material is decreased, and as the density of the flow control pattern 152 is decreased, the flow speed of the encapsulation material is increased, so that the density of the flow control pattern formed at the corner is greater than the density of the flow control pattern 152 formed on the four sides. As a result, the flow speed of the encapsulation material at the corner can be decreased to harden the encapsulation material before the encapsulation material over-flows beyond the dam DAM and then flow out of the display apparatus 100.

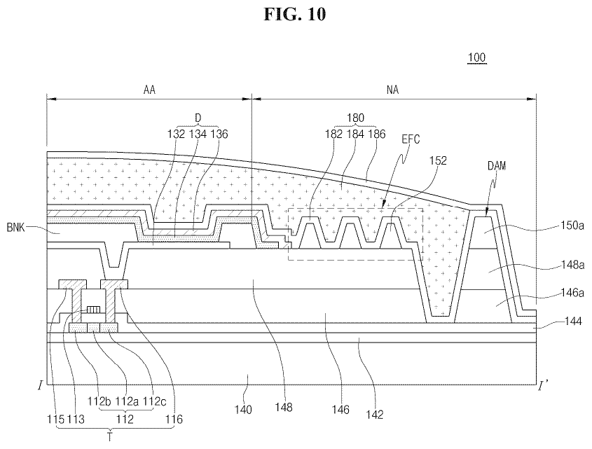

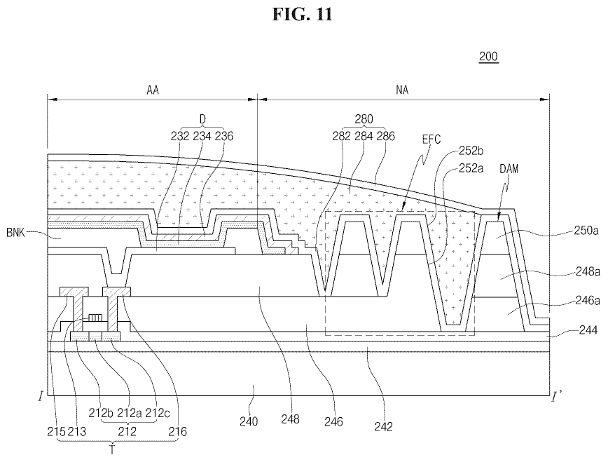

Hereinafter, the structure of the display apparatus 100 according to one or more embodiments of the present disclosure will be described in detail with reference to FIGS. 10 and 11.

FIG. 10 is a cross-sectional view showing the structure of the sub-pixel of the display apparatus 100, which is the cross-sectional view taken along line I-I′ of FIG. 4 according to a first embodiment of the present disclosure. At this time, FIG. 10 shows the display area AA and the non-display area NA for convenience of explanation. In reality, a number of thin film transistors and various lines are arranged in the display area AA and the non-display area NA, but for convenience of explanation, only the thin film transistor arranged in the display area AA are shown in FIG. 10.

As shown in FIG. 10, the substrate 140 includes the display area AA and the non-display area NA. The substrate 140 may be made of a hard material such as glass or a flexible plastic-based material.

In case where the substrate is made of the plastic-based material, the substrate may be made of at least one material of a polyimide, a polymethylmethacrylate, a polyethylene tereththalate, a Polyethersulfone, and a Polycarbonate, but is not limited thereto.

When the substrate 140 is made of polyimide, the substrate 140 may be made of a plurality of polyimide layers, and an inorganic layer may be further disposed between the polyimide layers, but is not limited thereto.

For example, the substrate 140 may include a first substrate, a second substrate, and a third substrate. The second substrate is disposed on the first substrate, and the third 1 substrate is disposed on the second substrate.

The first substrate and the third substrate may be substrates configured to support the components formed on the substrate. The first substrate and the third substrate may be flexible substrates made of a plastic material. In this case, the flexibility may be interpreted in the same way as bendable, unbreakable, rollable, and foldable properties and the like.

For example, the first substrate and the third substrate may include plastic. In this case, the first substrate and the third substrate may be referred to as plastic films or plastic substrates. For example, the first substrate and the third substrate may include at least one selected from a group consisting of polyester-based polymer, silicon-based polymer, acrylic-based polymer, polyolefin-based polymer, and a polymer thereof. For example, the first substrate and the third substrate may be polyimide substrates made of polyimide (PI). However, the present disclosure is not limited thereto.

The second substrate may include an inorganic insulating material. The second substrate may be an inorganic film formed between the first substrate and the third substrate. For example, the second substrate may be configured as a single layer or multilayer made of silicon nitride (SiNx) or silicon oxide (SiOx). For example, the second substrate may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

Further, the buffer layer 142 may delay the diffusion of moisture or oxygen that has penetrated the substrate 140.

The buffer layer 142 may be a single layer made of silicon oxide (SiOx) or silicon nitride (SiNx), or multi-layers thereof. When the buffer layer 142 is made of multiple layers, SiOx and SiNx may be alternately formed. For example, the buffer layer 142 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto. The buffer layer 142 may be omitted based on the type and material of the substrate 140, the structure and type of the thin film transistor, and the like.

A thin film transistor T is formed on the buffer layer 142 in the display area AA. For convenience of description, only the driving thin film transistor among various thin film transistors that may be disposed in the display area AA is illustrated, but other thin film transistors such as switching thin film transistors may also be included. In FIG. 10, the thin film transistor of a top gate structure is shown, but the thin film transistor is not limited to this structure and may be formed in other structures such as the thin film transistor of a bottom gate structure.

The thin film transistor includes a semiconductor pattern 112 disposed on the buffer layer 142, a gate insulating layer 144 covering the semiconductor pattern 112, a gate electrode 113 on the gate insulating layer 144, an interlayer insulating layer 146 covering the gate electrode 113, and a source electrode 115 and a drain electrode 116 on the interlayer insulating layer 146.

The semiconductor pattern 112 may be formed of a semiconductor material, such as an oxide semiconductor, amorphous semiconductor, or polycrystalline semiconductor, but is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The amorphous semiconductor material may be made of amorphous silicon (a-Si), but it is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto. For example, the polycrystalline semiconductor may be made of low temperature poly silicon (LTPS) having high mobility, but is not limited thereto.

The semiconductor pattern 112 includes a channel region 112a in a central region and a source region 112b and a drain region 112c which are doped layers at both sides of the channel region 112a.

The gate insulating layer 144 may be formed in the display area AA and the non-display area NA or formed only in the display area AA. The gate insulating layer 144 may be composed of a single layer or multiple layers made of an inorganic material such as SiOx or SiNx, but it is not limited thereto. For example, the gate insulating layer 144 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

The gate electrode 113 is made of a metal. For example, the gate electrode 113 may be formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto.

The interlayer insulating layer 146 may be made of the organic material such as photo-acryl, or the interlayer insulating layer 146 may formed of the single layer or the multiple layers made of the inorganic material such as SiOx or SiNx, but is not limited thereto. For example, the interlayer insulating layer 146 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto. Further, the interlayer insulating layer 146 may be formed of the multi layers of the organic material layer and the inorganic material layer, but is not limited thereto.

The source electrode 115 and the drain electrode 116 are formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto. The source electrode 115 and the drain electrode 116 may be respectively contacted to the source region 112b and the drain region 112c of the semiconductor through contact holes formed in the gate insulating layer 144 and the interlayer insulating layer 146.

Not shown in FIG. 10, a bottom shield metal layer may be disposed on the substrate 140 under the semiconductor pattern 112. The bottom shield metal layer reduces or minimizes a backchannel phenomenon caused by charges trapped in the substrate 140 to prevent afterimages or deterioration of transistor performance. The bottom shield metal layer may be composed of the single layer or the multi layers made of titanium (Ti), molybdenum (Mo), or an alloy thereof, but is not limited thereto.

A planarization layer 148 is formed on the substrate where the thin film transistor T is disposed. The planarization layer 148 may be formed of the organic material such as photoacrylic, but is not limited thereto. The planarization layer 148 may include a plurality of layers including the inorganic layer and the organic layer.

A light emitting device D is disposed on the planarization layer 148 in the display area AA. The light emitting device D includes a first electrode 132, an organic layer 134, and a second electrode 136.

The first electrode 132 is disposed on the planarization layer 148 and electrically connected to the drain electrode 115 of the thin film transistor T through the contact hole formed in the planarization layer 148. The first electrode 132 may be formed of at least one of silver (Ag), aluminum (Al), gold (Au), molybdenum (Mo), tungsten (W), chromium (Cr), or an alloy thereof. Further, the first electrode 132 may be formed of a transparent metal oxide material such as indium tin oxide (ITO) or indium zinc oxide (IZO).

When the display apparatus 100 is a top emission type display apparatus, the first electrode 132 may further include an opaque conductive material layer to function as a reflective electrode that reflects light. When the display apparatus 100 is a bottom emission type display apparatus, the first electrode 132 may be made of the transparent conductive material such as ITO or IZO.

A bank layer BNK is formed at the boundary between the sub-pixels on the planarization layer 148. The bank layer 152 may be a barrier wall to define sub-pixels. The bank layer BNK divides each sub-pixel to prevent light of a specific color output from adjacent pixels from being mixed and output.

The bank layer BNK is made of at least one material of the inorganic insulating material such as SiNx or SiOx, the organic insulating material such as BenzoCycloButene, acrylic resin, epoxy resin, phenolic resin, polyamide resin, or the photosensitizer including black pigment, but it is not limited thereto.

The bank layer BNK may be formed to be black or colored. For example, when the bank layer BNK includes a black material, external light, internal reflected light, and/or scattered light scattered from the side surface of the first electrode 132 may be suppressed from entering the thin film transistor, and the deterioration of luminance of the display apparatus may be improved. The bank layer BNK may be disposed so as to cover an end (or a partial area) of the first electrode 132.

The light emitting layer 134 is formed on the upper surface of the first electrode 132, the inclined surface of the bank layer BNK, or the partial region of the upper surface of the bank layer BNK.

The light emitting layer 134 is formed in the R, G, and B sub pixels and may include an R-emitting layer for emitting red light, a G-emitting layer for emitting green light, and a B-emitting layer for emitting blue light. For example, the light emitting layer 134 may include an organic light emitting layer, an inorganic light emitting layer, a nano-sized material layer, a quantum dot layer, a micro-LED light emitting layer, or a mini-LED light emitting layer, but is not limited thereto.

The light emitting layer 134 may further include an electron injecting layer for injecting electrons into the light emitting layer, a hole injecting layer for injecting holes into the light emitting layer, an electron transporting layer for transporting the injected electrons to the light emitting layer, a hole transporting layer for transporting the injected holes to the light emitting layer, an electron blocking layer, and a hole blocking layer, but is not limited thereto.

The second electrode 136 is disposed on the light emitting layer 134 and may be formed of the single layer or the multi layers made of the metal or the alloy thereof. Further, the second electrode 136 may be made of the transparent metal oxide material such as ITO or IZO, but is not limited thereto.

When the display apparatus 100 is the top emission type, the second electrode 136 may be made of the half-transparent conductive material that transmits light. For example, the second electrode 188 may be made of at least one or more of the alloys such as LiF/Al, CsF/Al, Mg:Ag, Ca/Ag, Ca:Ag, LiF/Mg:Ag, LiF/Ca/Ag, or LiF/Ca:Ag.

When the display apparatus 100 is the bottom emission type, the second electrode 136 may be the reflective electrode made of the opaque conductive material. For example, the second electrode 188 may be made of at least one or more of silver (Ag), aluminum (Al), gold (Au), molybdenum (Mo), tungsten (W), chromium (Cr), or alloys thereof.

Further, the light emitting device D may be formed in a tandem structure. The tandem structure may include a plurality of organic light emitting layers and a charge generating layer disposed between the organic light emitting layers. The charge generating layer is disposed to adjust the charge balance between the plurality of organic light emitting layers, and may be formed of a plurality of layers including a first charge generating layer and a second charge generating layer. The charge generating layer may include an N-type charge generating layer and a P-type charge generating layer. In this case, the charge generating layer may be formed of the organic layer doped with an alkali metal such as Li, Na, K, or Cs or an alkaline earth metal such as Mg, Sr, Ba, or Ra, but is not limited thereto.

An encapsulation layer 180 is formed in the display area AA and the non-display area NA to seal the light emitting device (D). When the light emitting device D is exposed to impurities such as moisture or oxygen, a pixel shrinkage phenomenon in which the light emitting area is reduced or the defect such as a dark spot in the light emitting area may occur. Further, moisture or oxygen penetrating into the light emitting device D oxidizes the metal electrode. The encapsulation layer 180 blocks impurities such as the oxygen and the moisture from the outside to prevent defects of the light emitting device D and various electrodes.

The encapsulation layer 180 may be formed of a first encapsulation layer 182, a second encapsulation layer 184, and a third encapsulation layer 186, but is not limited thereto. The encapsulation layer 180 may be formed of two layers having organic layer and inorganic layer or four or more layers having organic layers and inorganic layers.

The first encapsulation layer 182 and the third encapsulation layer 186 may be made of the inorganic material such as SiOx or SiNx, but are not limited thereto. The first encapsulation layer 182 and the third encapsulation layer 186 may be formed using a vacuum film forming method such as chemical vapor deposition (CVD) or atomic layer deposition (ALD), but are not limited thereto. The second encapsulation layer 184 may be made of the organic insulating material such as acrylic resin, epoxy resin, polyimide, polyethylene, or silicon oxycarbon (SiOC), but is not limited thereto. Further, the third encapsulation layer 186 may be made of thin metal (Face Seal Metal), but is not limited thereto.

Not shown in FIG. 10, a touch member may be disposed on the encapsulation layer 180. The touch member can detect external touch information using the user's finger or a touch pen.

A dam DAM is formed in the non-display area NA. The dam DAM is formed in the non-display area NA in a closed curve shape to surround the display area AA. When the insulating material having fluidity is coated to form the second encapsulation layer 184, the insulating material flowing out of the display apparatus 100 is blocked by the dam DAM.

The dam DAM can be made of various materials. As shown in FIG. 10, the dam DAM may include a first layer 146a, a second layer 148a, and a third layer 150a. At this time, the first layer 146a may be formed of the same material as the interlayer insulating layer 146 in the same process, and the second layer 148a may be formed of the same material as the planarization layer 148 in the same process. Further, the third layer 150a may be formed of the same material as the bank layer BNK in the same process. However, the present disclosure is not limited thereto.

The dam may be formed of two layers. At this time, the first layer and the second layer may be formed of layers corresponding to the planarization layer 148 and the bank layer BNK, respectively, and the first layer and the second layer may be formed of layers corresponding to the interlayer insulating layer 146 and the bank layer BNK, respectively. Further, the first layer and the second layer may be formed of layers corresponding to the interlayer insulating layer 146 and the planarization layer 148, respectively. In addition, the dam DAM may be formed of layers made of the different material from the layer in the display area AA.

The dam may be formed of two layers. At this time, the first layer and the second layer may be formed of layers corresponding to the planarization layer 148 and the bank layer BNK, respectively, and the first layer and the second layer may be formed of layers corresponding to the interlayer insulating layer 146 and the bank layer BNK, respectively. Further, the first layer and the second layer may be formed of layers corresponding to the interlayer insulating layer 146 and the planarization layer 148, respectively. In addition, the dam DAM may be formed of layers made of the different material from the layer in the display area AA.

The flow control unit EFC is disposed in the non-display area AA. Since the flow control unit EFC controls the spreading speed of the organic material when the organic material is coated to form the second encapsulation layer 184, so that the second encapsulation layer 184 is formed in the entire area of the display apparatus 100 and the organic material is not flowing out of the display apparatus 100 beyond the dam DAM.

The flow control unit EFC may include a plurality of flow control patterns 152. The flow control pattern 152 may be formed of oval-shaped, circular-shaped, or polygon-shaped protrusions. The flow control pattern 152 may be made of the same material as the bank layer BNK. That is, the flow control pattern 152 is made of at least one material of the inorganic insulating material such as SiNx or SiOx, the organic material such as BCB (BenzoCycloButene), acryl resin, epoxy resin, phenolic resin, polyamide resin, and polyimide resin, and a photosensitive agent containing black pigment. At this time, the flow control pattern 152 may be formed through the same process as the bank layer BNK.

The first encapsulation layer 182 is formed on the flow control pattern 152, and a second encapsulation layer 184 and the third encapsulation layer 186 are formed thereon. The first encapsulation layer 182 on the flow control pattern 152 may be surface treated to have hydrophobic properties. When the organic material is dispensed to form the second encapsulation layer 184, since the protruding area of the first encapsulation layer 182 protruded by the flow control pattern 152 has hydrophobic properties, the organic material is not over-flow beyond the upper area of the flow control pattern 152 and is flow only along the edges of the flow control pattern 152, thereby increasing the flow path of the organic material.

As described above, the display apparatus according to one or more embodiments of the present disclosure can achieve the following effects by providing a flow control unit EFC.

First, in the present disclosure, the flow control unit is disposed in the non-display area to control the flow of the organic material for forming the encapsulation layer, so that the organic material can be spread in the entire area of the display apparatus 100 and is not flow out of the display apparatus 100.

Second, in the present disclosure, the flow control pattern formed in the non-display area can block moisture or oxygen penetrating from the outside or extend the penetration path of moisture or oxygen, so that it can efficiently block moisture or oxygen penetrating from the outside.

FIG. 11 is a cross-sectional view showing the display apparatus 200 according to a second embodiment of the present disclosure. At this time, descriptions of the same structures as in FIG. 10 will be omitted or simplified, and only other structures will be described in detail.

As shown in FIG. 11, the thin film transistor T and the light emitting device D are disposed in the display area AA of the substrate 240, and the dam DAM is disposed in the non-display area (NA).

The thin film transistor T includes the semiconductor layer 212 disposed on the buffer layer 242, the gate electrode 214 disposed on the gate insulating layer 244, and the source electrode 215 and the drain electrode 216 disposed on the interlayer insulating layer 246.

The light emitting device D includes the first electrode 232, the organic layer 234, the second electrode 236. The first electrode 232 may be the anode electrode and the second electrode 236 may be the cathode electrode.

The first electrode 232 may be made of at least one of silver (Ag), aluminum (Al), gold (Au), molybdenum (Mo), tungsten (W), chromium (Cr), or alloys thereof. Further, the first electrode 232 may be made of a transparent metal oxide material layer, such as indium tin oxide (ITO) or indium zinc oxide (IZO).

The second electrode 236 is made of a translucent alloy such as LiF/Al, CsF/Al, Mg:Ag, Ca/Ag, Ca:Ag, LiF/Mg:Ag, LiF/Ca/Ag, and LiF/Ca:Ag, or the metal such as silver (Ag), aluminum (Al), gold (Au), molybdenum (Mo), tungsten (W), and chromium (Cr). Further, the second electrode 236 may be made of the transparent metal oxide that transmits light, such as ITO or IZO.

The encapsulation layer 280 including the first encapsulation layer 282 made of the inorganic material, the second encapsulation layer 284 made of the organic material, and the third encapsulation layer 236 made of the inorganic material is disposed over the light emitting device D.

The dam DAM is formed of the first layer 248a and the second layer 250a to prevent the organic materials from overflowing the display apparatus 200 when the second encapsulation layer 284 is formed. At this time, the first layer 248a may be made of the same material as the planarization layer 248 in the same process, and the second layer 250a may be made of the same material as the bank layer BNK in the same process.

The flow control unit EFC is formed between the display area AA and the dam DAM in the non-display area NA along the perimeter of the display area AA. When forming the second encapsulation layer 284, the flow control unit EFC controls the flow of the organic material so that the second encapsulation layer 284 is formed in entire area of the display apparatus 200, but the organic material is not flowing out of the display apparatus 200 beyond the dam DAM.

The flow control unit EFC is formed of a plurality of flow control patterns 252 disposed on the interlayer insulating layer 246. Each flow control pattern 252 includes the first flow control layer 252a and the second flow control layer 252b thereon. At this time, the first flow control layer 252a may be made of the same material through the same process as the planarization layer 248, and the second flow control layer 252b may be made of the same material through the same process as the bank layer BNK. However, the present disclosure is not limited thereto, and the first and second flow control layers 252a and 252b may be made of the different material from the planarization layer 248 and the bank layer BNK, respectively.

The first encapsulation layer 282 is formed on the flow control pattern 252, and the first encapsulation layer 282 on the flow control pattern 252 is reformed to have hydrophobic properties. When the organic material for forming the second encapsulation layer 284 is coated, the dispensed organic material does not flow beyond the area having hydrophobic characteristics but flows along the edge of the flow control pattern 252. Therefore, the flow path of the organic material is increased and the flow speed is decreased. Further, by varying the size and/or density of the flow control pattern 252 depending on the location, it is possible to control the flow speed of the organic material.

A display apparatus according to various embodiments of the present disclosure may be described as follows.

A display apparatus according to one or more embodiments of the present disclosure may comprise a substrate including a display area having a plurality of sub-pixels and a non-display area; a dam disposed in the non-display area; an encapsulation layer including an encapsulation material and formed in the display area and the non-display area; and a flow control unit for controlling flow of the encapsulation material, the flow control unit being disposed between the display area and the dam in the non-display area to surround the display area.

According to one or more embodiments of the present disclosure, the display apparatus may further comprise a transistor and a light emitting device disposed in each sub-pixel of the display area; a planarization layer covering the transistor; and a bank layer disposed between the sub-pixels over the planarization layer.

According to one or more embodiments of the present disclosure, the transistor may include a semiconductor layer over the substrate; a gate insulating layer on the semiconductor layer; a gate electrode on the gate insulating layer; an interlayer insulating layer on the gate electrode; and a source electrode and a drain electrode on the interlayer insulating layer.

According to one or more embodiments of the present disclosure, the flow control unit may include a plurality of flow control patterns on the planarization layer.

According to one or more embodiments of the present disclosure, the flow control pattern may be made of the same material as the bank layer.

According to one or more embodiments of the present disclosure, the flow control unit may include a plurality of flow control patterns on the interlayer insulating layer.

According to one or more embodiments of the present disclosure, the flow control pattern may include a first flow control layer on the interlayer insulating layer, the first flow control layer being made of the same material as the planarization layer; and a second flow control layer on the first flow control layer, the second flow control layer being made of the same material as the bank layer.

According to one or more embodiments of the present disclosure, the encapsulation layer may include a first encapsulation layer covering the light emitting device and the flow control pattern; a second encapsulation layer on the first encapsulation layer; and a third encapsulation layer on the second encapsulation layer.

According to one or more embodiments of the present disclosure, the first encapsulation layer on the flow control pattern may be protruded upward by the flow control pattern.

According to one or more embodiments of the present disclosure, the protruding area of the first encapsulation layer may have hydrophobic characteristics.

According to one or more embodiments of the present disclosure, the flow control pattern may be one of an elliptical shape, a circular shape, and a polygonal shape.

According to one or more embodiments of the present disclosure, a size of the flow control pattern may be increased from the display area to the dam.

According to one or more embodiments of the present disclosure, the size of the flow control pattern may be increased linearly, exponentially, or logarithmically from the display area to the dam.

According to one or more embodiments of the present disclosure, the density of the flow control pattern may be increased from the display area toward the dam.

According to one or more embodiments of the present disclosure, the density of the flow control pattern may be increased linearly, exponentially, or logarithmically from the display area to the dam.

According to one or more embodiments of the present disclosure, the size of the flow control pattern disposed on a corner portion of the substrate may be larger than the size of the flow control pattern disposed on four sides of the substrate.

According to one or more embodiments of the present disclosure, the density of the flow control patterns disposed on corners of the substrate may be greater than the density of the flow control patterns disposed on four sides of the substrate.

The display apparatus according to one or more embodiments of the present disclosure may comprise a substrate including a display area having a plurality of sub-pixels and a non-display area; an encapsulation layer including an encapsulation material and formed in the display area and the non-display area; and a flow control unit for controlling flow of the encapsulation material, the flow control unit being disposed in the non-display area to surround the display area.

According to one or more embodiments of the present disclosure, the flow control unit may include a plurality of flow control patterns under the encapsulation layer.

According to one or more embodiments of the present disclosure, the flow control pattern may be one of an elliptical shape, a circular shape, and a polygonal shape.

According to one or more embodiments of the present disclosure, a size of the flow control pattern may be increased in a direction from the display area to the non-display area.

According to one or more embodiments of the present disclosure, the size of the flow control pattern may be increased linearly, exponentially, or logarithmically in a direction from the display area to the non-display area.

According to one or more embodiments of the present disclosure, the density of the flow control pattern may be increased in a direction from the display area to the non-display area.

According to one or more embodiments of the present disclosure, the density of the flow control pattern may be increased linearly, exponentially, or logarithmically in a direction from the display area to the non-display area.

According to one or more embodiments of the present disclosure, the size of the flow control pattern disposed on a corner portion of the substrate may be larger than the size of the flow control pattern disposed on four sides of the substrate.

According to one or more embodiments of the present disclosure, the density of the flow control patterns disposed on corners of the substrate may be greater than the density of the flow control patterns disposed on four sides of the substrate.

The above description and the accompanying drawings are merely illustrative of the technical spirit of the present disclosure, and those of ordinary skill in the art to which the present disclosure pertains can combine configurations within a range that does not depart from the essential characteristics of the present disclosure, various modifications or variations such as separation, substitution and alteration will be possible. Therefore, the embodiments disclosed in the present disclosure are not intended to limit the technical spirit of the present disclosure, but to explain, and the scope of the technical spirit of the present disclosure is not limited by these embodiments.

What is claimed is:

1. A display apparatus, comprising:
a substrate including a display area having a plurality of sub-pixels, and a non-display area;
a dam in the non-display area;
an encapsulation layer including an encapsulation material, the encapsulation layer in the display area and the non-display area; and
a flow control unit that controls a flow of the encapsulation material, the flow control unit between the display area and the dam in the non-display area, and the flow control unit surrounds the display area.

2. The display apparatus of claim 1, further comprising:
a transistor and a light emitting device in each sub-pixel of the plurality of sub-pixels of the display area;
a planarization layer that covers the transistor; and
a bank layer between the plurality of sub-pixels and over the planarization layer.

3. The display apparatus of claim 2, wherein the transistor includes:
a semiconductor layer over the substrate;
a gate insulating layer on the semiconductor layer;
a gate electrode on the gate insulating layer;
an interlayer insulating layer on the gate electrode; and
a source electrode and a drain electrode on the interlayer insulating layer.

4. The display apparatus of claim 3, wherein the flow control unit includes a plurality of flow control patterns on the planarization layer.

5. The display apparatus of claim 4, wherein a flow control pattern of the plurality of flow control patterns includes a same material as the bank layer.

6. The display apparatus of claim 3, wherein the flow control unit includes a plurality of flow control patterns on the interlayer insulating layer.

7. The display apparatus of claim 6, wherein a flow control pattern of the plurality of flow control patterns includes:
a first flow control layer on the interlayer insulating layer, the first flow control layer including a same material as the planarization layer; and
a second flow control layer on the first flow control layer, the second flow control layer including a same material as the bank layer.

8. The display apparatus of claim 4, wherein the encapsulation layer includes:
a first encapsulation layer that covers the light emitting device and the flow control pattern;
a second encapsulation layer on the first encapsulation layer; and
a third encapsulation layer on the second encapsulation layer.

9. The display apparatus of claim 8, wherein the first encapsulation layer on the flow control pattern is protruded upward by a flow control pattern of the plurality of flow control patterns.

10. The display apparatus of claim 9, wherein a protruding area of the first encapsulation layer has hydrophobic characteristics.

11. The display apparatus of to claim 4, wherein a flow control pattern of the plurality of flow control patterns has one of an elliptical shape, a circular shape, and a polygonal shape.

12. The display apparatus of claim 4, wherein a size of each flow control pattern of the plurality of flow control patterns increases in a direction from the display area toward the dam.

13. The display apparatus of claim 12, wherein the size of each flow control pattern of the plurality of flow control patterns increases in the direction from the display area toward the dam linearly, exponentially, or logarithmically.

14. The display apparatus of claim 4, wherein a density of each flow control pattern of the plurality of flow control patterns increases in a direction from the display area toward the dam.

15. The display apparatus of claim 14, wherein the density of each flow control pattern of the plurality of flow control patterns increases in the direction from the display area toward the dam linearly, exponentially, or logarithmically.

16. The display apparatus according of claim 4, wherein a size of a first flow control pattern of the plurality of flow control patterns on a corner portion of the substrate is larger than a size of a second flow control pattern of the plurality of flow control patterns on four sides of the substrate.

17. The display apparatus of to claim 4, wherein a density of a first subset of the plurality of flow control patterns on corners of the substrate is greater than a density of a second subset of the plurality of flow control patterns on four sides of the substrate.

18. A display apparatus, comprising:
a substrate including a display area having a plurality of sub-pixels, and a non-display area;
an encapsulation layer including an encapsulation material, the encapsulation layer in the display area and the non-display area; and
a flow control unit that controls a flow of the encapsulation material, the flow control unit is in the non-display area and surrounds the display area.

19. The display apparatus of claim 18, wherein the flow control unit includes a plurality of flow control patterns under the encapsulation layer, and a size of each flow control pattern of the plurality of flow control patterns or a density of each flow control pattern of the plurality of flow control patterns increases in a direction from the display area toward the non-display area.

20. The display apparatus according of claim 19, wherein a first size of a first control pattern of the plurality of flow control patterns on a corner portion of the substrate is larger than a second size of a second flow control pattern of the plurality of flow control patterns on four sides of the substrate, or a first density of the first control pattern is greater than a second density of the second flow control pattern.
